(19) United States
(12) Patent Application Publication
(10) Pub. No.: US 2022/0068649 A1
(43) Pub. Date: Mar. 3, 2022

(54) BCD IC WITH GATE ETCH AND SELF-ALIGNED IMPLANT INTEGRATION

(71) Applicant: Texas Instruments Incorporated, Dallas, TX (US)

(72) Inventors: Mona M. Eissa, Allen, TX (US); Jason R. Heine, Plano, TX (US); Pushpa Mahalingam, Richardson, TX (US); Henry Litzmann Edwards, Garland, TX (US); James Robert Todd, Plano, TX (US); Alexei Sadovnikov, Sunnyvale, CA (US)

(21) Appl. No.: 17/411,431

(22) Filed: Aug. 25, 2021

Related U.S. Application Data
(60) Provisional application No. 63/071,008, filed on Aug. 27, 2020.

(51) Int. Cl. H01L 21/266; H01L 29/78; H01L 29/66; H01L 29/10; H01L 29/423

(52) U.S. Cl. CPC H01L 21/266; H01L 29/7816; H01L 29/42368; H01L 29/6659; H01L 29/1095; H01L 29/66681

(57) ABSTRACT

A method of fabricating an IC includes providing a substrate including a semiconductor surface having well diffusions for a plurality of devices including bipolar, complementary metal oxide semiconductor (CMOS), and double-diffused MOS (DMOS) devices. A polysilicon layer is deposited on a dielectric layer over the semiconductor surface, an anti-reflective coating (ARC) layer is formed on the polysilicon layer, and a photoresist pattern is formed on the ARC layer. The ARC layer is etched in areas exposed by the photoresist pattern to define areas including gate areas having the ARC layer on the polysilicon layer. The photoresist pattern is removed. Polysilicon etching is performed in areas lacking the ARC layer to form polysilicon gates having a remaining ARC portion of the ARC layer thereon. A self-aligned ion implant uses the remaining ARC portion as an additional implant blocking layer for the polysilicon gates, and the remaining ARC portion is stripped.

CROSS-REFERENCE TO RELATED APPLICATION(S)

This application claims priority to U.S. Provisional Patent Application No. 63/071,008, filed Aug. 27, 2020, which is incorporated herein by reference in its entirety.

### FIELD

This Disclosure relates to semiconductor integrated circuit (IC) devices having polysilicon gates, more particularly to the polysilicon gate etch and subsequent self-aligned gate ion implants.

### BACKGROUND

Bipolar complementary metal oxide semiconductor (BiCMOS) is a semiconductor IC technology that integrates two formerly separate semiconductor technologies, those of the bipolar junction transistor and the CMOS transistor, in a single integrated circuit (IC) device. Bipolar junction transistors offer relatively high speed, high gain, and low output resistance, which are properties well-suited for high-frequency analog amplifiers, where CMOS technology offers high input resistance and is well-suited for providing relatively simple, low-power logic gates.

For advanced analog with power and digital ICs that integrate >=5V high-voltage (HV) devices which generally have an extended drain commonly referred to herein as double diffused MOS (DMOS) devices (that can be implemented as vertical devices or lateral devices)), analog (CMOS or bipolar) devices, and low-voltage (LV) CMOS digital devices <=1.5V that function as digital devices, such ICs are generally referred to in the industry as BCD (Bipolar-CMOS-DMOS) IC devices. BCD ICs thus include bipolar devices, CMOS devices, and DMOS devices. A unique gate loop integration is needed to adapt the LV CMOS device's polysilicon gate features for the gates of the DMOS devices. This enables an improvement in the HV devices and analog (bipolar and CMOS) devices' figure of merits (FOMs), as well as a corresponding IC die area shrink and an IC die cost reduction.

An anti-reflective coating (ARC) layer, such as a silicon rich silicon nitride (SiN) layer or other silicon nitride comprising layer, may be formed over a reflective electrically conductive layer, commonly a doped polysilicon layer (that can also be undoped polysilicon layer at that point in the process) in the conventional case of polysilicon gate technology. A photoresist pattern is then printed over the ARC layer on the polysilicon layer using photolithography. During this gate level photolithography, the ARC layer absorbs radiation waves, such as conventional deep ultraviolet (DUV) radiation. Being absorbed by the ARC layer, the radiation waves are prevented from undesirably reflecting off the underlying layer, such as the top surface of a polysilicon gates.

A traditional gate etch, generally comprising a masked plasma etch process, is used to etch outside of the intended polysilicon features to define the polysilicon features including the polysilicon gates, and then the photoresist and the ARC layer are stripped. The polysilicon gate then by itself is generally used to act as a self-aligned gate to block ion implants from reaching the channel region in the semiconductor surface under the polysilicon gate. The self-aligned implants include lightly doped drain (LDD) implants for the metal oxide semiconductor (MOS) devices. A spacer may then be added to the polysilicon gate sidewalls, and then a source/drain implant may follow.

### SUMMARY

This Summary is provided to introduce a brief selection of disclosed concepts in a simplified form that are further described below in the Detailed Description including the drawings provided. This Summary is not intended to limit the claimed subject matter's scope.

Disclosed aspects include a method of fabricating an IC that comprises a polysilicon layer that is deposited on a dielectric layer over the semiconductor surface, at least one ARC layer is formed on the polysilicon layer, and a photoresist pattern is formed on the ARC layer. The ARC layer is etched in areas exposed by the photoresist pattern to define areas including gate areas having the ARC layer on the polysilicon layer. The photoresist pattern is removed, generally comprising plasma photoresist removal. Polysilicon etching occurs in areas lacking the ARC layer to form polysilicon gates, where the resulting polysilicon gates have their own remaining ARC portion of the ARC layer. At least one self-aligned ion implant uses the remaining ARC portion as an additional implant blocking layer for the polysilicon gates for blocking the ion implantation from reaching the semiconductor surface under the polysilicon gates, and the remaining ARC portion is then stripped off.

### BRIEF DESCRIPTION OF THE DRAWINGS

Reference will now be made to the accompanying drawings, which are not necessarily drawn to scale, wherein:

FIG. 1 is a flow chart that shows steps in an example method for forming a BCD IC, according to an example aspect.

FIGS. 2A-2L are cross-sectional diagrams showing processing progression for an example method of forming a BCD IC shown for a single MOS device including a polysilicon gate delineation process comprising forming an ARC layer on the polysilicon gate then self-aligned implantation, according to an example aspect. FIG. 2A shows results after forming an initial patterned gate stack comprising photoresist on an ARC layer stack shown as an optional top ARC layer on a bottom ARC layer on a polysilicon layer that is on a gate dielectric layer which is on the semiconductor surface of a substrate. FIG. 2B shows results after an optional trim process for trimming the photoresist which narrows the photoresist lines.

FIG. 2C shows results after etching the ARC layer stack lateral to the photoresist. A portion of the ARC layer lateral to the photoresist on the gates is shown after this etching process.

FIG. 2D shows results after an ARC layer over etch to complete removal of the remaining portion of the ARC layer lateral to the photoresist. FIG. 2E shows results after stripping of the photoresist showing the formation of a thin oxide film on the surface of the polysilicon layer lateral to the ARC layer stack. FIG. 2F shows results after an etch that removes the thin oxide film that was on the polysilicon layer shown in FIG. 2E.

FIG. 2G shows results after an initial primary etch of the polysilicon layer that is shown as a non-selective etch which removes most of the polysilicon layer lateral to the ARC layer stack, and also removes a portion of the ARC layer stack shown so that only a portion of the bottom ARC layer remains. FIG. 2H shows results after a relatively high selectivity polysilicon etch that completes the removal of the polysilicon layer lateral to the remaining ARC layer so that a gate stack remains with the portion of the bottom ARC layer on the patterned polysilicon layer now shown as polysilicon gate.

FIG. 2I shows arrows representing a self-aligned LDD ion implant performed after the polysilicon etch is completed with the portion of the bottom ARC layer retained, that together with the polysilicon gate serves as the implant blocking stack for these relatively deep ion implants. The LDD regions are also shown. FIG. 2J shows results after sidewall spacers are formed on the sidewalls of the gate stack. FIG. 2K includes arrows indicating at least one additional ion implantation performed, shown as a source and drain (S/D) ion implant, that utilizes the gate stack for implant blocking to form S/D regions, with the spacers providing implant blocking out a lateral distance from the gate stack. FIG. 2L shows the resulting exposed polysilicon gate after removing the remaining ARC layer portion from over the gate stack.

FIG. 3 is a cross-sectional view of a disclosed BCD IC, according to an example aspect.

FIG. 4 is a flowchart showing for steps for a method of gate CD measurement feedback, according to an example aspect.

### DETAILED DESCRIPTION

Example aspects are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this disclosure.

Technology scaling of BCD IC processes for digital and power content area shrink have typically been accompanied with voltage scaling of the CMOS transistors. However, below a certain voltage rating, the analog (the bipolar and CMOS) device performance degrades due to an acceleration in power-voltage scaling. Reducing the power supply voltage that the device is operated at reduces the maximum signal energy, which makes obtaining a high Signal-to-Noise ratio (SNR) harder to obtain.

This Disclosure recognizes some BCD IC processes due to process scaling have reduced layer thicknesses including a reduced thickness of the polysilicon layer used for the gate of the MOS devices. In one specific example newer BCD IC process, for example, the polysilicon thickness is 1,200 Å as compared to the previous process node that had a polysilicon thickness of 1,600 Å. It is recognized that a reduced polysilicon layer thickness may not be sufficient to block the self-aligned implant(s), such as the double-diffused well (DWELL), n-type LDD (NLDD), p-type LDD (PLDD) and p-type deep well (PDWELL), from undesirably implanting through the polysilicon gate to reach the channel region of the substrate surface under the polysilicon gate, which can cause a threshold voltage (Vt) shift for the MOS devices.

Integration of relatively HV (3 to 5V) CMOS devices and 5 to 40 V DMOS devices such as laterally diffused metal oxide semiconductor (LDMOS) devices with technology scaling is recognized to present certain challenges. As these voltage ratings remain constant from one node to another, LDD and DWELL junctions used in these MOS devices are recognized to generally not be able to scale with BCD IC technology scaling.

For example, the blocking power of the gate for self-aligned implants such as NLDD, PLDD, and DWELL is reduced with technology scaling as the polysilicon layer thickness also shrinks with technology scaling. For example, a self-aligned NLDD implant is needed for tight threshold voltage (Vt) control of 3 V to 5 V NMOS devices.

Disclosed aspects include utilizing the gate level ARC layer for polysilicon layer patterning, and by leaving at least a portion of it on the polysilicon gate at the time of the self-aligned implants the ARC layer acts as an additional implant blocking layer that is in addition to the polysilicon gate conventionally used alone for blocking self-aligned gate implantation. The increased thickness of the gate stack due to the presence of the ARC layer thereon enables more effective gate stack blocking of self-aligned relatively high energy implants, such as LDD implants and DWELL implants. The as-formed ARC layer thickness can be chosen such that it does not significantly reduce the gate stack reflectivity during polysilicon gate patterning.

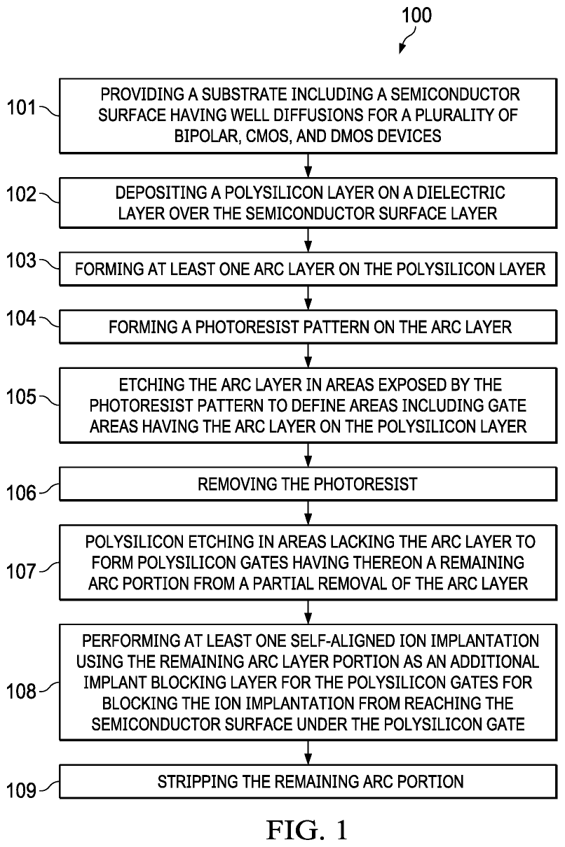

FIG. 1 is a flow chart that shows steps in an example method 100 for forming a BCD IC, according to an example aspect. Step 101 comprises providing a substrate including a semiconductor surface having well diffusions for a plurality of bipolar, CMOS, and DMOS devices which can be lateral devices and/or vertical devices, or a combination of lateral and vertical devices. Step 102 comprises depositing a polysilicon layer on a dielectric layer which may be termed a gate dielectric layer over the semiconductor surface layer. The thickness of the polysilicon layer is generally less than 1,500 Å such as 1,000 Å to 1,300 Å, which is generally thinner as compared to prior technology nodes.

Step 103 comprises forming at least one ARC layer on the polysilicon layer. The ARC layer(s) generally has a thickness (collective thickness in the case of two more ARC layers) in the range 300 Å to 1,600 Å. One ARC layer arrangement comprises a layer of silicon oxynitride (SiON) on a layer of silicon rich silicon nitride. Conventional silicon nitride is known to have Si:N in a 3:4 ratio, and a Si:N ratio larger than 0.75:1 is considered herein to be silicon rich silicon nitride, such as in a range between 0.75:1 to 1.5:1 of Si:N. For example, 55%:45% of Si:N can be used as a composition for silicon rich silicon nitride.

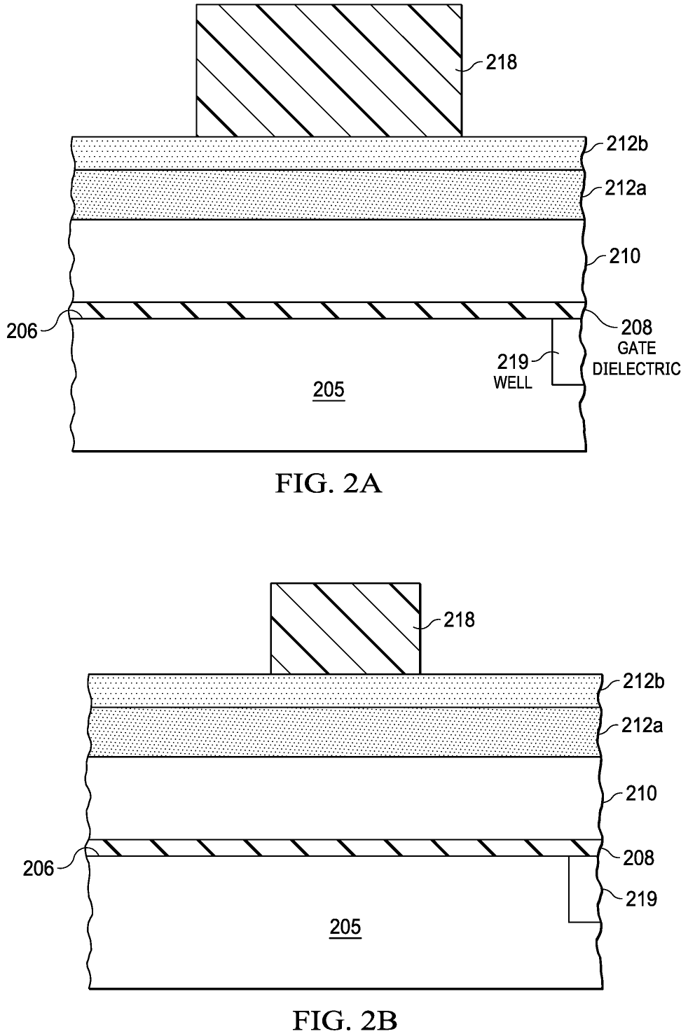

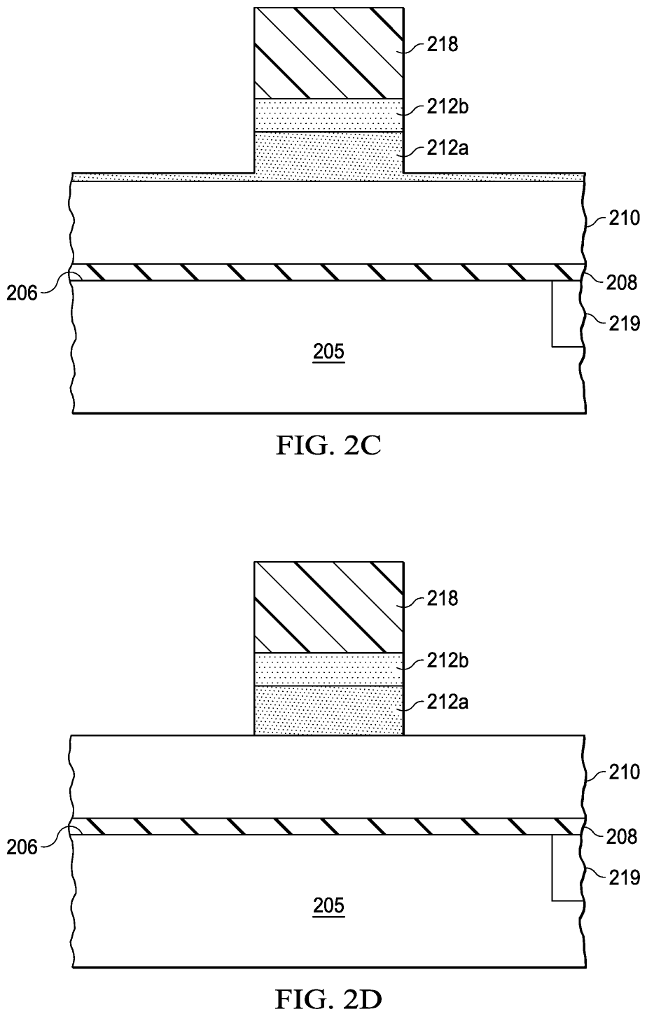

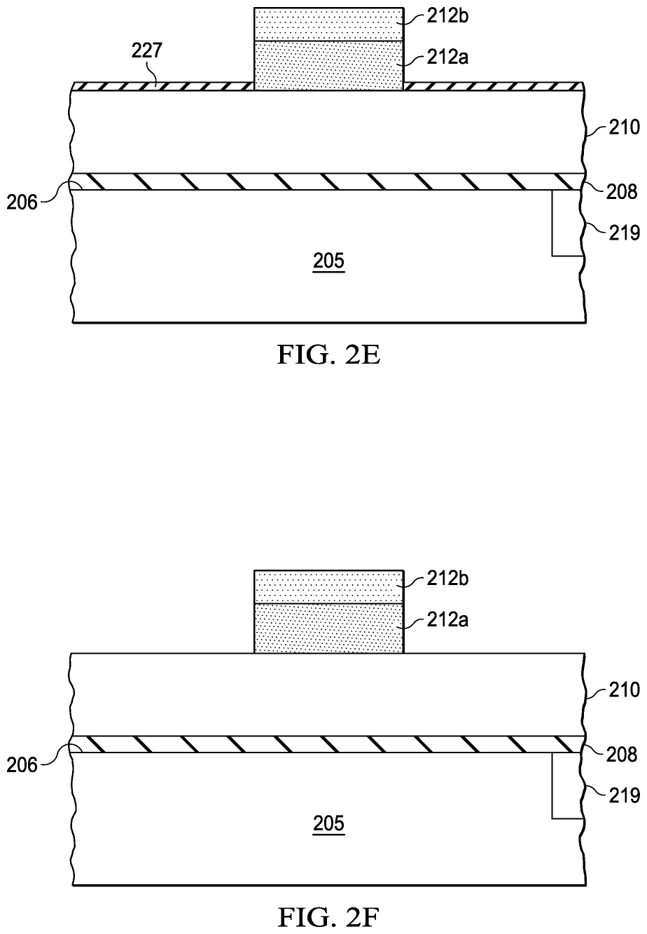

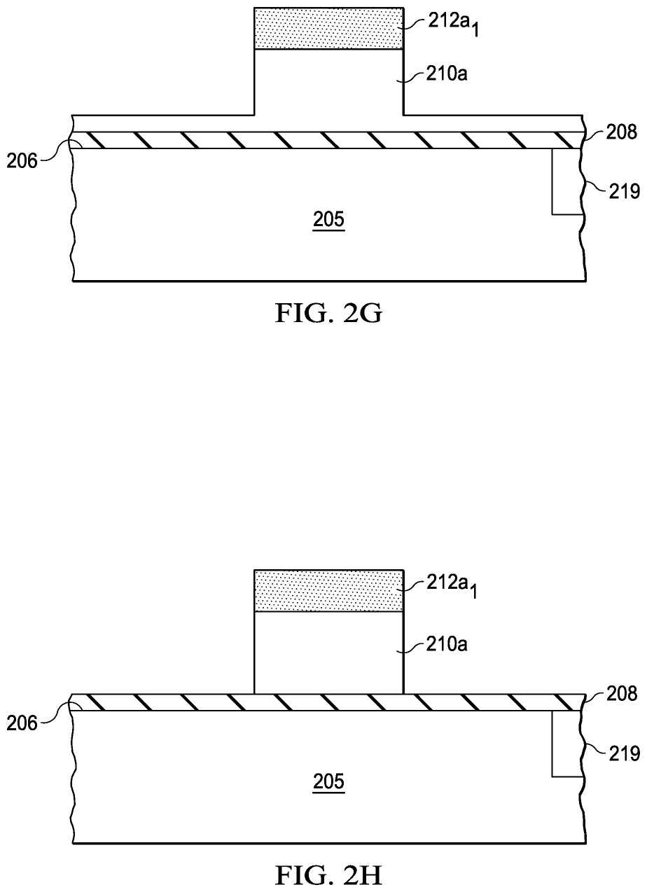

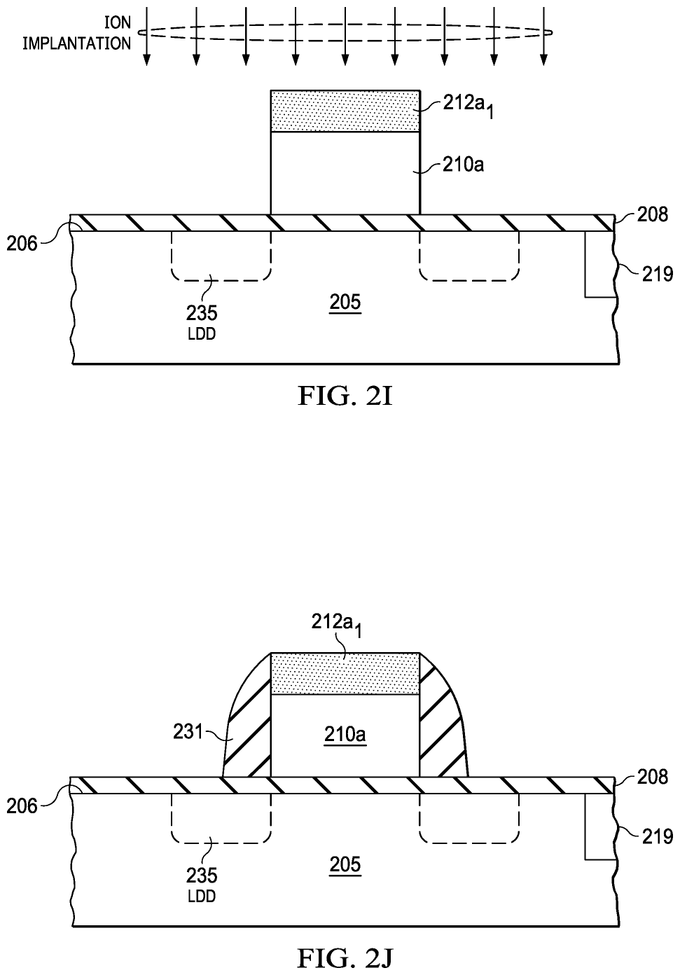

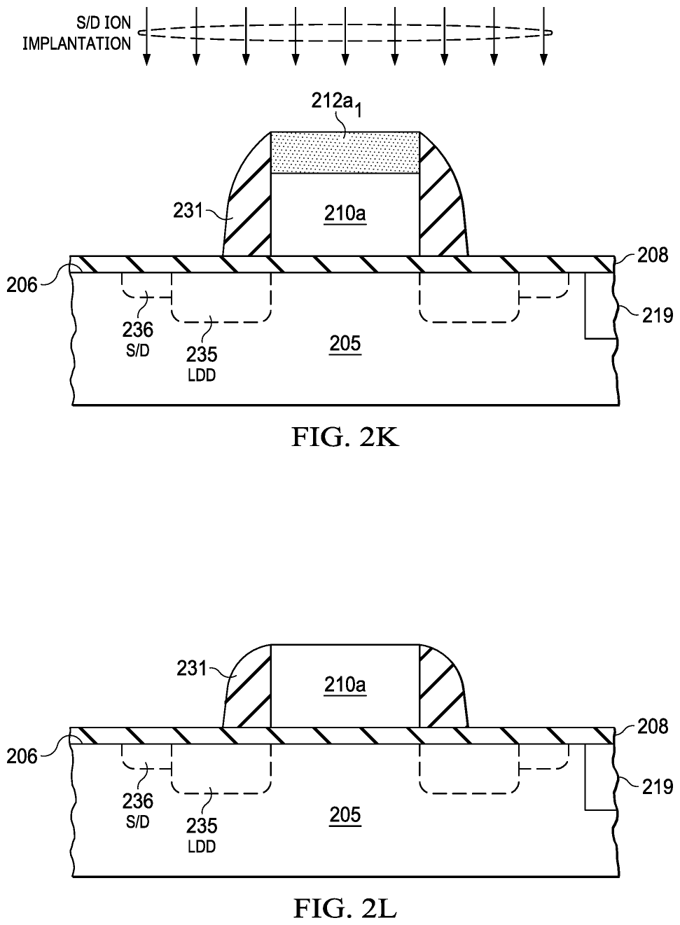

Step 104 comprises forming a photoresist pattern on the ARC layer. FIG. 2A shows a gate stack comprising photoresist 218 on an optional top ARC layer 212b on bottom ARC layer 212a, that is on the polysilicon layer 210 which is on a gate dielectric layer 208 that is on a semiconductor surface 206 on the substrate 205. The substrate 205 can comprise silicon, silicon-germanium, or another semiconductor material. There is a plurality of wells formed in the semiconductor surface 206 shown for simplicity in FIG. 2A as a single well 219. One particular substrate 205 arrangement is an epitaxial surface as the semiconductor surface 206 on a bulk silicon substrate shown as substrate 205. FIG. 2B shows results after an optional trim process for the photoresist 218. The photoresist trim step removes some of the photoresist 218 to cause the photoresist lines to be narrower.

Step 105 comprises etching the top ARC layer 212b, 212a in areas exposed by the photoresist pattern to define areas including gate areas having the ARC layer on the polysilicon layer 210. FIG. 2C shows results after an initial ARC layer etch that may be termed a main ARC layer etch, and FIG. 2D shows results after what may be termed an ARC layer overetch that completes the removal of the remaining portion of the bottom ARC layer 212a lateral to the photoresist 218.

Step 106 comprises removing the photoresist 218, generally using a plasma removal process, with the results shown in FIG. 2E which shows a silicon oxide film 227 that may be formed on top of the polysilicon layer 210 from the plasma removal process. FIG. 2F shows results after what can be termed a breakthrough etch which etches through the silicon oxide film 227 shown in FIG. 2E to expose the surface of the polysilicon layer 210.

Step 107 comprises polysilicon etching in areas lacking the ARC layer 212b, 212a to form polysilicon gates having thereon a remaining ARC portion from a partial removal of the ARC layer. The polysilicon etching can comprise a non-selective etch that removes most of the polysilicon layer 210 lateral to the gate stacks and some of the ARC layer 212b, 212a on the gate stacks, and then a selective etch polysilicon etch that may etch the remaining polysilicon layer 210 lateral to the gate stacks.

FIG. 2G shows the results after the non-selective etch, and FIG. 2H shows results after the selective polysilicon etch. The remaining portion of the ARC layer stack is a portion of the bottom ARC layer 212a now shown as 212a₁, and the polysilicon gate is shown as 210a. The remaining ARC layer portion 212a₁ can be about at least 50% of the ARC layer(s) thickness before the etching of the ARC layer(s), and wherein the remaining ARC portion 212a₁ after the non-selective etch and the selective polysilicon etch can be seen to be at a sidewall taper angle of at least 80 degrees relative to a top surface of the polysilicon gate 210a. A sidewall taper angle of at least 80 degrees can be important because the HV components which use the self-aligned implants could otherwise have their Vt, they are specific on-resistance (Rsp), and/or long-term reliability adversely impacted in the case of an ARC sidewall angle <80 degrees relative to the polysilicon layer.

Step 108 comprises performing at least one self-aligned ion implantation using the remaining ARC layer portion 212a₁ as an additional implant blocking layer for the polysilicon gates for blocking the ion implantation from reaching the semiconductor surface 206 under the polysilicon gate 210a. For example, a self-aligned LDD implant and at least one self-aligned well implant may be performed. FIG. 21 shows arrows representing a self-aligned LDD ion implant performed after the polysilicon etch with the remaining ARC layer portion 212a₁ retained, that together with the polysilicon gate 210a serves as the implant blocking stack for these relatively deep ion implants. The LDD regions 235 are also shown. The LDD implant, and possibly other implants such as well implants, is/are performed before sidewall spacer formation as described below.

The method may then include forming a spacer on sidewalls of the gate stack with the results shown in FIG. 2J, with the spacer shown as 231, and then performing an additional implantation (e.g., source/drain implantation), with the results shown in FIG. 2K. The source/drain regions are shown as S/D region 236 in FIG. 2K.

Step 109 comprises stripping the remaining ARC layer portion 212a₁ with the results shown in FIG. 2L. Hot phosphoric acid (H3PO4) may be used to strip the remaining ARC portion in the case the remaining ARC layer portion 212a₁ comprises silicon nitride or silicon oxynitride. The anneals employed post-LDD and S/D implants are typically rapid thermal annealing (RTA), for dopant activation and just enough to ensure that dopants from the LDD and S/D implants have diffused to the channel. Comparatively, long furnace anneals after LDD and S/D implants are typically avoided in advanced digital CMOS and analog CMOS nodes to enable a node-over-node footprint shrink of CMOS & HV active devices and improved Vt and current drive matching performance of analog components. Conventional multilayer metal processing followed by formation of a passivation layer(s) with a pattern to expose the bond pads of the top metal layer generally follows to complete the ICs on the wafers.

The total as-deposited ARC layer(s) thickness can be selected based on a combination of the following factors: (i) optimal focus-exposure at polysilicon layer patterning that would meet the minimum polysilicon gate width and space requirements, (ii) the maximum amount of ARC layer which would be consumed during the polysilicon gate etch; and (iii) the minimum ARC layer thickness needed for the gate stacks to block high energy implants for the DMOS and CMOS devices. The ARC thickness together with the polysilicon layer thickness can be selected to be sufficient to block relatively high energy implants such as LDD and DWELL implants. In one particular example, these respective implants can comprise phosphorus (P³¹) at 70 keV and boron (B¹¹) at 30 keV.

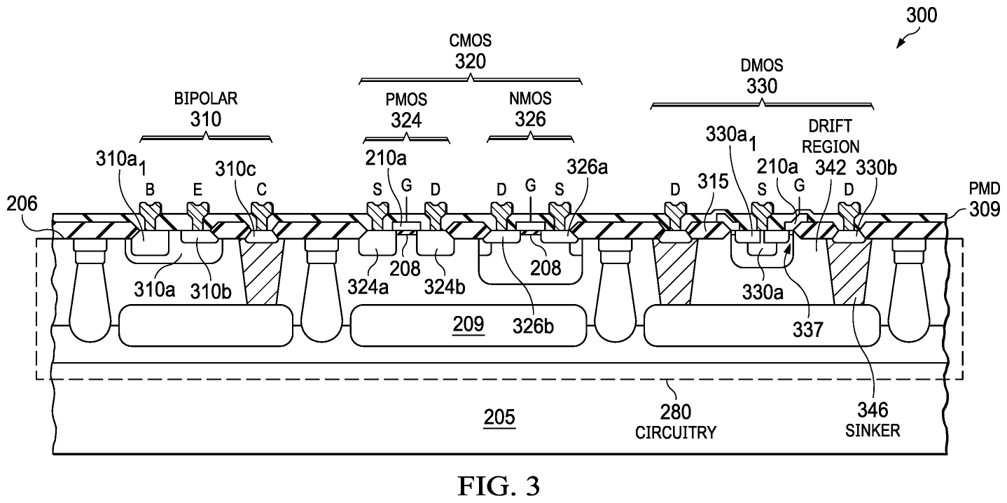

FIG. 3 is a cross sectional view of a disclosed BCD IC 300, according to an example aspect. The BCD IC 300 comprises a substrate 205 having a semiconductor surface 206 with circuitry 280 configured for a function formed in the semiconductor surface 206. Although the BCD IC 300 is shown having junction isolation, vertical dielectric isolation (such as shallow trench isolation (STI)) may also be used. The circuitry 280 includes bipolar devices shown as bipolar device 310, CMOS devices 320 shown as a PMOS device 324 and an NMOS device 326, and DMOS devices shown as 330. Although the DMOS device 330 is shown being a lateral device, as described above the DMOS device can also be a vertical device. There is also a patterned buried layer 209 shown under the bipolar device 310, under the CMOS devices 320, and under the DMOS device 330. A sinker diffusion 346 provides a low resistance connection from various diffusions in the semiconductor surface 206 to the buried layer 209. There is also a pre-metal dielectric (PMD) layer 309 shown over the semiconductor surface 206.

As used herein a DMOS device includes LDMOS devices and processes for forming such devices. Moreover, as used herein, an LDMOS device is synonymous with a lateral DMOS device having a gate stack with the polysilicon gate layer on the gate dielectric layer, and having a drift region separating the drain region from the source region.

BCD IC 300 includes field oxide 315 shown in a portion of the semiconductor surface 206. The circuitry 280 as known in the art comprises circuit elements (including transistors, and generally diodes, resistors, capacitors, etc.) formed in the semiconductor surface 206 configured together for realizing at least one circuit function such as analog (e.g., an amplifier, power converter or power field effect transistor (FET)), RF, digital, or a memory function.

The CMOS devices 320 and the DMOS device 330 both include a polysilicon gate 210a that has a thickness which is less than 1,500 Å, where the polysilicon gate 210a is on a gate dielectric layer 208, with the respective gates 210a shown in FIG. 3 as G. The source 324a and drain 324b of the PMOS device 324, the source 326a and the drain 326b of the NMOS device 326, and the source 330a and the drain 330b of the DMOS device 330 are all shown. As described above, the source 330a and drain 330b may include LDD regions that are generally aligned with the gate stack after implant, but after diffusion extends laterally including under the gate as shown. The DMOS device 330 can have an effective channel length (L_{eff}) of less than (<) 0.4 μm, where the L_{eff} is shown by the arrow marked 337 which is defined as the spacing between the drift region 342 and the source contact 330a₁ of the source 330a.

Although not shown for the MOS devices, the CMOS devices 320 and the DMOS device 330 can also include LDDs. The drawn channel length for the CMOS devices is defined herein as the physical width of the polysilicon gate 210a, which is generally less than (<) 0.8 μm.

The bipolar device 310 shown including base 310a having base contact 310a₁ and emitter 310b includes at least one diffusion common to at least one of the CMOS devices 320 and the DMOS device 330. The common diffusions can be associated with the drift region implant for forming the drift region 342 for the DMOS device 330, and forming the deep well implants with CMOS devices 320 and the DMOS devices 330.

Disclosed aspects also include a polysilicon gate etch process developed for the increased ARC thickness used for disclosed aspects that is generally able to produce repeatability and reproducibility for the gate critical dimension (CD) and for the gate profile. The maximum time allowed during ARC etch is generally increased to accommodate a thicker ARC layer(s). The etch time range for etching the ARC layer(s) can generally be 50 to 70 seconds. Because for disclosed methods the ARC layer is not stripped until after patterning and ion implantation steps, the feedback loop relying on post ARC strip measurements of the parent wafer lot is recognized to take too long for lot-to-lot process tuning.

All gate CD control can be performed during the resist trim step rather than also including a SiON hardmask trim step. This maximizes the resist trim step time to provide trim time margin for incoming pattern CD variation. Including a SiON hardmask trim step means some trimming is occurring at an etch step other than the resist trim step, and this means the resist trim step would be shorter, which can become a problem if the trim step becomes too short to control the process. The temperature gradient across the electro-static chuck during the plasma resist trim step can be designed to minimize cross-wafer CD uniformity, where the temperature setpoints for the outer and inner portions of the electro-static chuck during the resist trim step are set such that the non-uniformity of the post etch CDs across the wafer is minimized.

Disclosed aspects include automated control of parent lot etch trim times, which uses pre-etch clean gate CD measurement feedback from initial test wafers, and targets the pre-etch clean gate CD for the remainder of the wafers in the lot. Conventional gate etch processes have automated control for tuning the gate etch process to hit a post-ARC strip gate CD target for the remainder of the lot, which may be contrasted with the disclosed use of the pre-etch clean gate CD. This disclosed approach to gate CD measurement feedback is needed given the long time delay in receiving post ARC layer strip gate CD measurements results from keeping at least a portion of the ARC layer on top of the polysilicon layer during multiple self-aligned ion implants. This same approach can be used for other processes that remove the ARC layer before self-aligned implant(s).

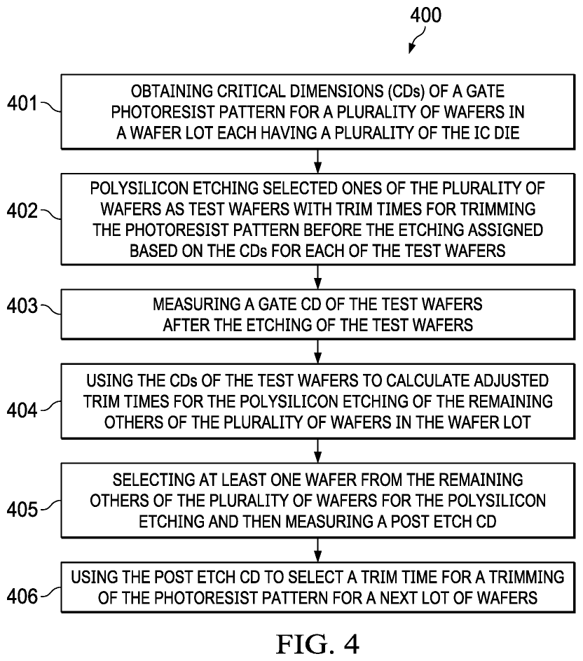

FIG. 4 shows steps in a method 400 of gate CD control flow for a BCD IC. Step 401 comprises obtaining CDs of a gate photoresist pattern for a plurality of wafers in a wafer lot each having a plurality of the IC die. Scatterometry can be used for obtaining the CDs. Step 402 comprises polysilicon etching selected ones of the plurality of wafers as test wafers with trim times for trimming the photoresist pattern before the etching assigned based on the CDs for each of the test wafers. Step 403 comprises measuring a gate CD of the test wafers after the etching of the test wafers. Step 404 comprises using the CDs of the test wafers to calculate adjusted trim times for the polysilicon etching of the remaining others of the plurality of wafers in the wafer lot. Step 405 comprises selecting at least one wafer from the remaining others of the plurality of wafers for the polysilicon etching, and then measuring a post etch CD. Step 406 comprises using the post etch CD to select a trim time for trimming of the photoresist pattern for a next lot of wafers.

Disclosed aspects can be used to form semiconductor die that may be integrated into a variety of assembly flows to form a variety of different devices and related products. The semiconductor die may include various elements therein and/or layers thereon, including barrier layers, dielectric layers, device structures, active elements and passive elements including source regions, drain regions, bit lines, bases, emitters, collectors, conductive lines, conductive vias, etc. Those skilled in the art to which this Disclosure relates will appreciate that many other aspects are possible within the scope of the claimed invention, and further additions, deletions, substitutions and modifications may be made to the described aspects without departing from the scope of this Disclosure.

1. A method of fabricating an integrated circuit (IC), comprising:
depositing a polysilicon layer on a dielectric layer over a semiconductor substrate;
forming an anti-reflective coating (ARC) layer on the polysilicon layer;
forming a photoresist pattern on the ARC layer;
etching the ARC layer in areas exposed by the photoresist pattern to define areas including gate areas having the ARC layer on the polysilicon layer;
removing the photoresist pattern;
etching the polysilicon layer in areas lacking the ARC layer to form polysilicon gates having a remaining ARC portion of the ARC layer thereon;
performing at least one self-aligned ion implantation using the remaining ARC portion as an additional implant blocking layer for the polysilicon gates, and
stripping the remaining ARC portion.

2. The method of claim 1, further comprising before stripping the remaining ARC portion forming a spacer on sidewalls of the polysilicon gates and then performing an additional ion implant.

3. The method of claim 1, wherein after the etching of the polysilicon layer i) a thickness of the remaining ARC portion is at least 50% of a thickness of the ARC layer before the etching of the polysilicon layer, and ii) the remaining ARC portion is at a sidewall taper angle of at least 80 degrees relative to a top surface of the polysilicon gates.

4. The method of claim 1, wherein the etching of the polysilicon layer comprises a plasma etch configured for etching polysilicon.

5. The method of claim 1, wherein the IC includes at least one laterally diffused metal oxide semiconductor (LDMOS) device.

6. The method of claim 1, wherein a thickness of the ARC layer immediately following the forming the ARC layer on the polysilicon layer is in a range from 800 to 2,500 Å, and wherein the ARC layer comprises silicon nitride.

7. The method of claim 1, wherein the forming of the ARC layer comprises forming a bottom ARC layer and then forming a top ARC layer on the bottom ARC layer that is a different material compared to the bottom ARC layer.

8. The method of claim 7, wherein the bottom ARC layer comprises silicon rich silicon nitride, and wherein the top ARC layer comprises silicon nitride.

9. The method of claim 1, further comprising trimming the photoresist pattern to narrow a line width.

10. The method of claim 1, further comprising before the etching of the ARC layer:
obtaining critical dimensions (CDs) of the photoresist pattern for a plurality of wafers in a wafer lot each having a plurality of the IC die;
trimming the photoresist pattern of selected first ones of the plurality of wafers as test wafers with trim times based on the CDs for each of the test wafers;
polysilicon etching the test wafers after trimming the photoresist pattern;
measuring a gate CD of the test wafers after the polysilicon etching of the test wafers;
using the gate CDs of the test wafers to calculate adjusted trim times for remaining others of the plurality of wafers in the wafer lot;
selecting at least one wafer from the remaining others of the plurality of wafers for the polysilicon etching and then measuring a post etch CD, and
using the post etch CD to select a trim time for a trimming of the photoresist pattern for a next lot of wafers.

11. A method of fabricating an integrated circuit (IC), comprising:
providing a substrate including a semiconductor surface having well diffusions for a plurality of devices, the plurality of devices including bipolar, complementary metal oxide semiconductor (CMOS), and double-diffused MOS (DMOS) devices;
depositing a polysilicon layer on a dielectric layer over the semiconductor surface;
forming anti-reflective coating (ARC) layers on the polysilicon layer comprising forming a bottom ARC layer and then forming a top ARC layer on the bottom ARC layer that is a different material compared to the bottom ARC layer;
forming a photoresist pattern on the top ARC layer;
etching the ARC layers in areas exposed by the photoresist pattern to define areas including gate areas having the ARC layers on the polysilicon layer;
removing the photoresist pattern;
etching the polysilicon layer in areas lacking the ARC layers to form polysilicon gates having a remaining ARC portion of the ARC layer thereon, wherein a thickness of the remaining ARC portion is at least 50% of a thickness of the ARC layers before the etching of the polysilicon layer, and wherein the remaining ARC portion is at a sidewall taper angle of at least 80 degrees relative to a top surface of the polysilicon gates;
performing at least one self-aligned ion implantation using the remaining ARC portion as an additional implant blocking layer for the polysilicon gates,
forming a spacer on sidewalls of the polysilicon gates and then performing an additional ion implant, and
stripping the remaining ARC portion.

12. The method of claim 11, wherein the bottom ARC layer comprises silicon rich silicon nitride, and wherein the top ARC layer comprises silicon nitride.

13. The method of claim 11, wherein a total thickness of the bottom and the top ARC layers immediately following the forming the ARC layers is in a range from 800 to 2,500 Å.

14. The method of claim 11, further comprising trimming the photoresist pattern to narrow a line width.

15. The method of claim 14, further comprising before the etching of the ARC layer:
obtaining critical dimensions (CDs) of the photoresist pattern for a plurality of wafers in a wafer lot each having a plurality of the IC die;
trimming the photoresist pattern of selected first ones of the plurality of wafers as test wafers with trim times based on the CDs for each of the test wafers;
polysilicon etching the test wafers after trimming the photoresist pattern;
measuring a gate CD of the test wafers after the polysilicon etching of the test wafers;
using the gate CDs of the test wafers to calculate adjusted trim times for the remaining others of the plurality of wafers in the wafer lot;
selecting at least one wafer from the remaining others of the plurality of wafers for the polysilicon etching and then measuring a post etch CD, and
using the post etch CD to select a trim time for a trimming of the photoresist pattern for a next lot of wafers.

16. The method of claim 11, wherein the DMOS devices include at least one laterally diffused metal oxide semiconductor (LDMOS) device.

17. The method of claim 11, wherein the etching of the polysilicon layer comprises a plasma etch configured for etching polysilicon.

18. An integrated circuit (IC), comprising:
a complementary metal oxide semiconductor (CMOS) device including a polysilicon gate layer that has a thickness less than 1,500 Å which is on a gate dielectric layer, with a source and drain structure, having a drawn channel length of less than (<) 0.8 μm;
a double diffused MOSFET (DMOS) device having a gate stack with the polysilicon gate layer on the gate dielectric layer, and having a drift region separating a drain region from a source region with an effective channel length (L_{eff}) of less than (<) 0.4 μm defined as a spacing between the drift region and the source region, and
a bipolar device including at least one diffusion common to at least one of the CMOS devices and the DMOS device.

19. The IC of claim 18, wherein the thickness of the polysilicon gate layer is less than 1,300 Å.

20. The IC of claim 18, wherein the DMOS device includes at least one laterally diffused metal oxide semiconductor (LDMOS) device.
